(19) United States
(12) Patent Application Publication
(10) Pub. No.: US 2026/0360447 A1
(43) Pub. Date: Nov. 12, 2026

(54) MEMORY DEVICE, LOGIC CONTROLLER AND METHOD THEREOF

(71) Applicant: Winbond Electronics Corp., Taichung City (TW)

(72) Inventors: Oron Michael, San Jose, CA (US); Dae Hyun Kim, San Ramon, CA (US)

(73) Assignee: Winbond Electronics Corp., Taichung City (TW)

(21) Appl. No.: 19/200,599

(22) Filed: May 6, 2025

(51) Int. Cl. G11C 16/32; G11C 16/16; G11C 16/26; G11C 16/34

(52) U.S. Cl. CPC G11C 16/32; G11C 16/16; G11C 16/26; G11C 16/3445

(57) ABSTRACT

A memory device which includes a memory array, a logic controller and an input/output (IO) circuit is introduced. The logic controller is configured to execute an embedded operation on at least one memory cell of the memory array. The logic controller includes a time counter which is configured to hold a time value representing a minimum time to finish the embedded operation. The time value of the time counter is set according to an address range of the at least one memory cell, and the time value of the time counter is decremented in accordance with an increment of an address in the address range of the at least one memory cell during an execution of the embedded operation. The IO circuit is configured to output the time value of the time counter.

### BACKGROUND

### Technical Field

The disclosure relates to a memory device, and more particularly relates to a memory device, a logic controller and a method thereof that can report a minimum remaining time to finish an execution of an embedded operation, thereby reducing power consumption and improving overall system performance of the memory device.

### Description of Related Arts

In a flash memory device, when a user starts an embedded operation by issuing a command to the flash memory device, the flash memory device will become busy for a certain length of time. While the flash memory device is busy, an access to the flash memory device is limited. The user can keep monitoring the device status (i.e., ready/busy status) with a status register read or just wait the maximum operation time defined by the specification of the flash memory device. However, the method of monitoring the status register or waiting the maximum time rise few system disadvantages. One, it will increase system's power consumption when keep monitoring the status of the flash memory device. Second, the system performance cannot be optimized to the best scenario.

It is desirable for a novel design of a memory device that may reduce power consumption and improve performance of the memory device.

### SUMMARY

In some embodiments of the disclosure, a memory device includes a memory array, a logic controller and an input/output (IO) circuit. The memory array includes a plurality of memory cells. The logic controller is connected to the memory array and is configured to execute an embedded operation on at least one memory cell among the memory cells of the memory array. The logic controller includes a time counter which is configured to hold a time value representing a minimum time to finish the embedded operation. The time value of the “time counter” is set according to an address range of the at least one memory cell, and the time value of the “time counter” is decremented in accordance with an increment of an address in the address range of the at least one memory cell during an execution of the embedded operation. The IO circuit is configured to output the time value of the time counter.

In accordance with the above embodiments, a logic controller which is configured to execute an embedded operation on at least one memory cell of a memory array is introduced. The logic controller includes an address register, an address counter and a time counter. The address register is configured to record an address range of the at least one memory cell where the embedded operation executes. The address counter is configured to increase an address in the address range during an execution of the embedded operation. The “time counter” is configured to hold a time value representing a minimum time to finish the embedded operation. The time value is set according to the address range of the at least one memory cell, and the time value is decremented in accordance with an increment of the address in the address range of the at least one memory cell during the execution of the embedded operation.

In accordance with the above embodiments, a method of a memory device comprising a memory array and a logic controller is introduced. The method includes steps of receiving a command to execute an embedded operation on at least one memory cell of the memory array; determining an initial time value for a time counter of the logic controller according to an address range of the at least one memory cell; setting initial time value as a time value of the time counter, wherein the time value represents a minimum time to finish the embedded operation; decrementing the time value of the time counter in accordance with an increment of an address in the address range of the at least one memory cell during an execution of the embedded operation; and outputting at least one of the time value of the time counter and status values of a status register upon a status register read command.

In the above embodiments, a memory device includes a built-in “time counter” which holds a time value representing a minimum time to finish an embedded operation. The time value of the time counter may be set according to an address range of memory cells on which the embedded operation executes and a type of the embedded operation. The time value can be decremented in response to an address increment in the address range of memory cells. The “time counter” could be decremented when address counter increments by one bit, one byte, one page or a certain range of addresses. The time value of the time counter can be output upon a status register read command, and the time counter may be configured using a configuration bit. Since the minimum time to finish the embedded operation is reported by the memory device, the memory device does not need to repeatedly read the status register to monitor the status of the memory device. Accordingly, the power consumption is saved, the system performance is improved, and the system performance can be optimized to the best scenario. Furthermore, the time value of the time counter can be readable during different statuses including a suspend status of the memory device, thereby improving flexibility and operability of the memory device.

To make the above features and advantages provided in one or more of the embodiments of the disclosure more comprehensible, several embodiments accompanied with drawings are described in detail as follows.

### BRIEF DESCRIPTION OF THE DRAWINGS

FIG. 1 is a schematic diagram of a memory device in accordance with some embodiments.

FIG. 2 is a diagram illustrating an implementation of a time counter of the memory device in FIG. 1 in accordance with some embodiments.

FIG. 3A illustrates a diagram of signals in the memory device when the time counter is enabled in accordance with some embodiments.

FIG. 3B illustrates a diagram of signals in the memory device when the time counter is disabled in accordance with some embodiments.

FIG. 4 is a flowchart diagram of a method of a memory device in accordance with some embodiments.

### DESCRIPTION OF THE EMBODIMENTS

References are made in detail to the present preferred embodiments of the invention, examples of which are illustrated in the accompanying drawings. Wherever possible, the same reference numbers are used in the drawings and the description to refer to the same or like parts.

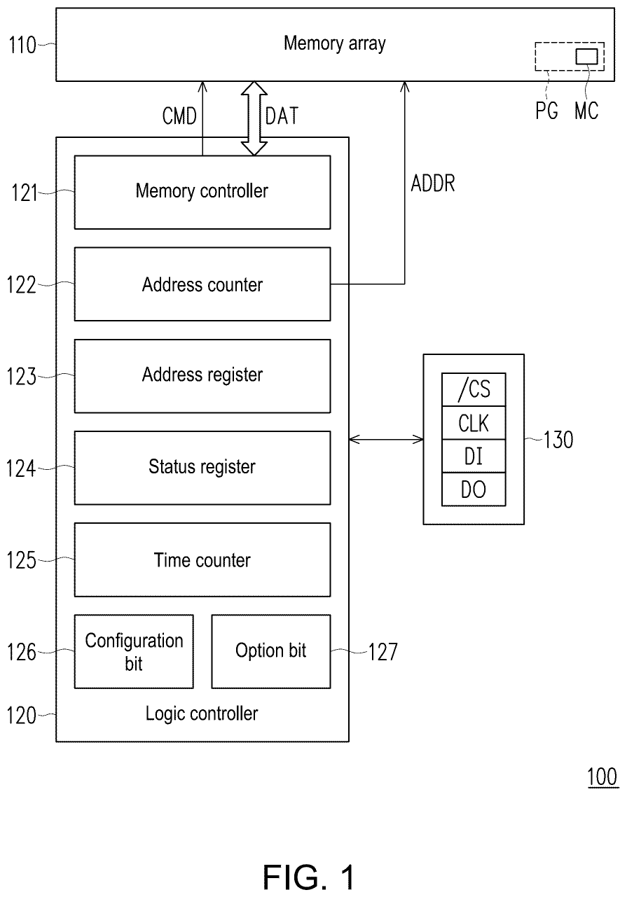

FIG. 1 illustrates a schematic diagram of a memory device 100 which includes a memory array 110, a logic controller 120 and an input/output (IO) circuit 130 in accordance with some embodiments. The memory array 110 may include a plurality of pages PG, where each of the pages PG includes a plurality of memory cells MC. Multiple pages of the memory array 110 may be arranged in a sector, multiple sectors may be arranged in a block, and multiple blocks may be arranged in a chip. The memory array may include a plurality of chips. The memory array 110 may also include other circuitries essential for the normal operations of the memory array 110. For example, the memory array 110 may further include a plurality of bit lines, a plurality of word lines, and a plurality of source lines. Embedded operations such as read operations, program operations, and erase operations may be performed on the memory cells (MC) of the memory array 110 via the bit lines, word lines, and source lines. In some embodiments, the embedded operations are performed at the level of a memory cell, a memory byte, a page, a sector, a block, or a chip. The memory cell, the memory byte, the page, the sector, the block and/or the chip may be collectively referred to as a memory unit, where the size of the memory unit for the embedded operations may vary depending on the type of the embedded operation and the designed requirements. For example, read and program operations can be performed at a bit level, a byte level, a page level, while the erase operation can be performed at the sector level (i.e., sector erase), block level (i.e., block erase), or chip level (i.e., chip erase). The memory device 100 may be a flash memory device, such as a NAND flash memory device or a NOR flash memory device.

The logic controller 120 is connected to the memory array 110 and is configured to control operations of the memory device 100. The logic controller 120 may include a memory controller 121, an address counter 122, an address register 123, a status register 124 and a time counter 125. The logic controller 120 may further include a configuration bit 126 which is configured to enable or disable the time counter 125 and at least one option bit 127 which is configured to set a clock frequency for the time counter 125. The configuration bit 126 and the at least one option bit 127 can be set during setting process of the status register 124, and the configuration bit 126 can be in any register of the logic controller 120. Although each of the configuration bit 126 and the at least one option bit 127 is illustrated as a single bit in FIG. 1, the disclosure is not limited thereto. The configuration bit 126 and the at least one option bit 127 can be multi-bit values.

The memory controller 121 may control the embedded operation on the memory array 110 such as the read operation, the program operation or the erase operation. To perform the read operation to read data in a target memory unit, the memory controller 121 may issue a read command to the memory array 110 and control the address counter 122 to provide the address ADDR (i.e., bit address, byte address or page address) of the target memory unit to the memory array 110. To perform the program operation to write data to a target memory unit of the memory array 110, the memory controller 121 may issue a program command and data to be written (i.e., data DAT) to the memory array 110 and control the address counter 122 to provide the address ADDR of the target memory unit to the memory array 110. To perform the erase operation to erase a target memory unit of the memory array 110, the memory controller 121 may issue an erase command to the memory array 110 and control the address counter 122 to provide the address ADDR of the target memory unit to be erased to the memory array 110.

The erase operation can be the sector erase, the block erase or the chip erase. To perform the sector erase, the memory controller 121 may send the addresses of the target sector and a sector erase command to the memory array 110. To perform the block erase, the memory controller 121 may send the addresses of the target block to be erased and a block erase command to the memory array 110. To perform the chip erase, the memory controller 121 may send the addresses of the target chip to be erased and a chip erase command to the memory array 110. The read command, the program command and the erase command are collectively represented as a command CMD in FIG. 1.

In some embodiments, each of the sector erase, the block erase and the chip erase may include a plurality of sub-operations. For example, the sector erase may include a pre-program operation, an erase operation, an erase verify operation, a soft program operation, a soft verify operation and a refresh operation. When the sector erase is executed, the sub-operations included in the sector erase will be performed sequentially. In other words, the pre-program operation, the erase operation, the erase verify operation, the soft program operation, the soft verify operation and the refresh operation included in the sector erase are sequentially executed. Similarly, the block erase or the chip erase are performed by sequentially executing the sub-operations included in the block erase or the chip erase.

The address register 123 is configured to record the addresses of memory units [symbol] i.e., addresses of bits, bytes, pages, sectors, blocks or chips) on which the embedded operation executes. When the read command is issued to read a target memory unit, the address register 123 may record the address of the target memory unit. When the program command is issued to write data to a target memory unit, the address register 123 may record the address of the target memory unit. When the erase command is issued to erase a target memory unit, the address register 123 may record an address of the target memory unit.

The address counter 122 may act as a pointer that identifies the address of the memory unit where the embedded operation or a sub-operation is currently executing. Once the embedded operation or the sub-operation is completed, the address counter 122 may increase and point to the next address among the addresses recorded in the address register 123.

The status register 124 is configured to provide a status of the memory device 100 such as a busy, ready and suspend statuses upon the status register read command. The busy status is defined by a busy bit in the status register 124, and the busy bit is set when the memory device 100 is executing the embedded operation such as the read operation, the program and the erase operation. When the embedded operation has been completed, the busy bit will be cleared, indicating that the memory device 100 is ready for further instructions. The suspend status is defined by a suspend bit in the status register 124, and the suspend bit is set after executing a suspend operation such as an erase suspend operation or a program suspend operation. The status register 124 may include additional bits to provide additional pieces of information or additional functionalities for the memory device 100, such as a write enable latch bit, a block protect bit, a sector protect bit, and the like.

The time counter 125 is configured to hold a time value that represents the minimum time required to complete the embedded operation. An initial time value of the time counter 125 may be set based on the address range of the memory units where the embedded operation needs to execute, and the type of the embedded operation or the types of sub-operations included in the embedded operation. In some embodiments, the larger the address range of the memory units where the embedded operation needs to execute, the larger the initial time value set for the time counter 125. The clock frequency of the time counter 125 may determine how quick the “time counter” decrements. The clock frequency of the time counter 125 can be set by at least one option bit 127 of the logic controller 120. Each type of the embedded operation may be associated with a number of clock cycles, and the initial time value of the time counter 125 may be set based on the number of clock cycles associated with the embedded operation. The number of clock cycles associated with the embedded operation refers to the number of clock cycles required to complete the embedded operation. When the embedded operation is the sector erase that includes sub-operations, the initial time value of the time counter 125 may be set based on the number of clock cycles associated with each sub-operation of the sector erase.

Table 1 shows the sub-operations in the sector erase for erasing a 4 KB sector (or 4,096-byte sector). Table 1 further shows a number of bytes associated with each sub-operation, the time per byte (i.e., the time required to process one byte), the clock cycles per byte (i.e., the number of clock cycles required to process one byte), and the number of clock cycles associated with each sub-operation of the sector erase. For example, the pre-program operation of the sector erase may operate on 4,096 bytes, where the time required to process one byte is 300 ns, and the number of clock cycles required to process one byte is 6 clock cycles. Accordingly, the number of clock cycles required to execute the pre-program operation on 4,096 bytes is 24,576 clock cycles. In other words, the pre-program operation of the sector erase is associated with 24,576 clock cycles. Similarly, the erase operation of the sector erase is associated with 1,000 clock cycles. The erase verify operation of the sector erase is associated with 12,288 clock cycles. The soft program operation of the sector erase is associated with 32,768 clock cycles, the soft verify operation of the sector erase is associated with 8, 192 clock cycles, and the refresh operation of the sector erase is associated with 24,576 clock cycles. In total, the sector erase is associated with 103,400 clock cycles, and this value may be set as the initial time value of the time counter 125 for the sector erase.

TABLE 1

| | number of | time per byte | clock cycles | number of |
|---|---|---|---|---|
| operation | bytes | [ns] | per byte | clock cycles |
| pre-program | 4,096 | 300 | 6 | 24,576 |
| erase | 1 | 50,000 | 1,000 | 1,000 |
| erase verify | 4,096 | 150 | 3 | 12,288 |
| soft program | 4,096 | 400 | 8 | 32,768 |
| soft verify | 4,096 | 100 | 2 | 8,192 |
| refresh | 4,096 | 300 | 6 | 24,576 |

In some embodiments, the time value of the time counter 125 is decremented in accordance with the increment of the address in the address range of the memory units recorded in the address register 123. The increment of the address in the address range of the memory units is monitored by the address counter 122. In some embodiments, each time the address counter 122 indicates that the address has incremented in an operation, the time counter 125 subtracts the number of clock cycles associated with that operation from its current time value to generate a new time value. For example, as shown in Table 1, each time the address increments during the pre-program operation, the time counter 125 is reduced by 6 clock cycles. Similarly, each time the address increments during the erase verify operation, the time counter 125 is reduced by 3 clock cycles. When reaching the last erased byte address in a sector, and the address is incremented, during erase verify, the time counter will be reduced by 1003 clock cycles, which is 1000 clock cycles for the erase and 3 clock cycles for the erase verify of last address of a byte in a sector. During the soft verify operation, the time counter 125 is reduced by 10 clock cycles each time the address increments, which is 8 clock cycles for soft program plus 2 clock cycles for soft verify; and during the refresh operation, the time counter 125 is reduced by 6 clock cycles each time the address increments. During the erase operation nor soft program, the time counter 125 will not be changed or reduced.

The time counter 125 can be enabled or disabled by configuring the configuration bit 126, and the time value of the time counter 125 can be output upon the status register read command. When the configuration bit is in the first logic state, the time counter 125 is enabled, and the values of the status register 124 and the time value of the time counter 125 can be output upon the status register read command. When the configuration bit is in the second logic state, the time counter 125 is disabled, and the time value of the time counter 125 will not be output upon the status register read command. The time value of the time counter 125 can be readable in many statuses of the memory device 100 including the suspend status.

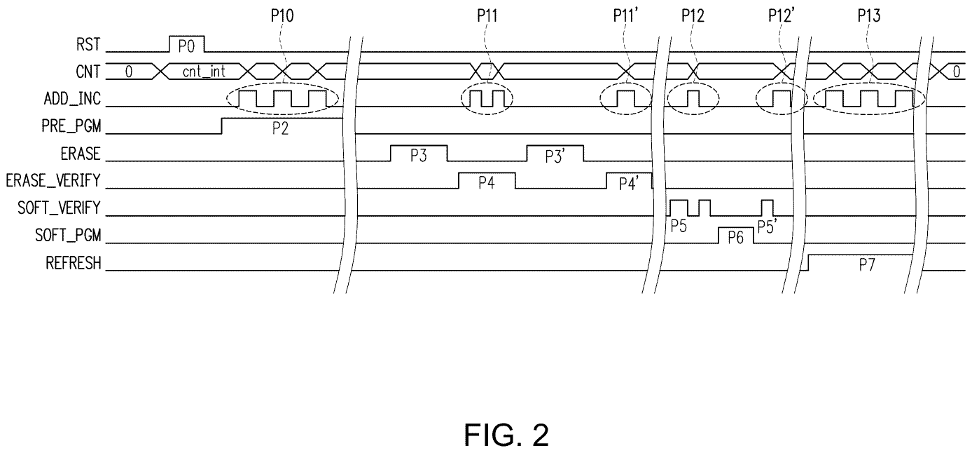

FIG. 2 illustrates an implementation of the time counter 125 of the memory device 100 in FIG. 1 in accordance with some embodiments. FIG. 2 shows diagrams of a reset signal RST, the time value CNT of the time counter 125, the address increment signal ADD_INC, the pre-program operation PRE_PGM, the erase operation ERASE, the erase verify operation ERASE_VERIFY, the soft verify operation SOFT_VERIFY, the soft program operation SOFT_PGM and the refresh operation REFRESH. Upon a pulse PO of the reset signal RST, the initial time value cnt_int corresponding to the embedded operation is loaded to the time counter 125. As the example shown in the Table 1, when the embedded operation is the sector erase, the initial time value cnt_int equivalent to 103,400 clock cycles can be loaded to the time counter 125 upon the pulse PO of the reset signal RST.

The address increment signal ADD_INC indicates an increment of the address indicated by the address counter 122. The address increment signal ADD_INC changes according to an increment of the address during executions of the pre-program operation PRE_PGM, the erase verify operation ERASE_VERIFY, the soft verify operation SOFT_VERIFY, the soft program operation SOFT_PGM and the refresh operation REFRESH. The increment of the address associated with the erase operation ERASE does not trigger the update or decrement of the time value CNT of the time counter 125.

As shown in FIG. 2, the pulse P2 of the pre-program operation PRE_PGM indicates the execution of the pre-program operation PRE_PGM, and the pulses P10 in the address increment signal ADD_INC indicates the increment of the address associated with the pre-program operation PRE_PGM. The increment of the address associated with the pre-program operation PRE_PGM triggers the decrement of the time value CNT of the time counter 125. As shown in Table 1, each time the address increments during the pre-program operation PRE_PGM, the time value of the time counter 125 can be reduced by 10 clock cycles.

The pulses P3 and P3′ of the erase operation ERASE indicate the execution of the erase operation ERASE. As shown in FIG. 2, the address increment signal ADD_INC does not update during the execution of the erase operation ERASE.

The pulses P4 and P4′ of the erase verify operation ERASE_VERIFY indicates the execution of the erase verify operation ERASE_VERIFY, and the pulses P11 and P11′ in the address increment signal ADD_INC indicate the increment of the address associated with the erase verify operation ERASE_VERIFY. The increment of the address associated with the erase verify operation ERASE_VERIFY triggers the decrement of the time value CNT of the time counter 125. As shown in Table 1, each time the address increments during the erase verify operation ERASE_VERIFY, the time value of the time counter 125 can be reduced by 4 clock cycles.

The pulses P5 and P5′ of the soft verify operation SOFT_VERIFY indicate the execution of the soft verify operation SOFT_VERIFY, and the pulse P6 of the soft program operation SOFT_PGM indicates the execution of the soft program operation SOFT_PGM. During the soft verify operation SOFT_VERIFY, the assumption is that every address will need a soft program operation SOFT_PGM. Therefore, every time the address counter increases, the time counter will be decremented by the time it takes to verify and program one time. The pulses P12 and P12′ in the address increment signal ADD_INC indicate the increment of the address associated with the soft verify operation SOFT_VERIFY and the soft program operation SOFT_PGM. The increment of the address associated with the soft verify operation SOFT_VERIFY and the soft program operation SOFT_PGM triggers the decrement of the time value CNT of the time counter 125.

The pulse P7 of the refresh operation REFRESH indicates the execution of the refresh operation REFRESH, and the pulse P13 in the address increment signal ADD_INC indicates the increment of the address associated with the refresh operation REFRESH. The increment of the address associated with the refresh operation REFRESH triggers the decrement of the time value CNT of the time counter 125. As shown in Table 1, each time the address increments during the refresh operation REFRESH, the time value of the time counter 125 can be reduced by 12 clock cycles.

In the above implementations of the time counter 125, the minimum time to finish the embedded operation is represented by the time value of the time counter 125. Accordingly, the memory device 100 does not need to frequently read the status register 124, thereby saving power consumption of the memory device.

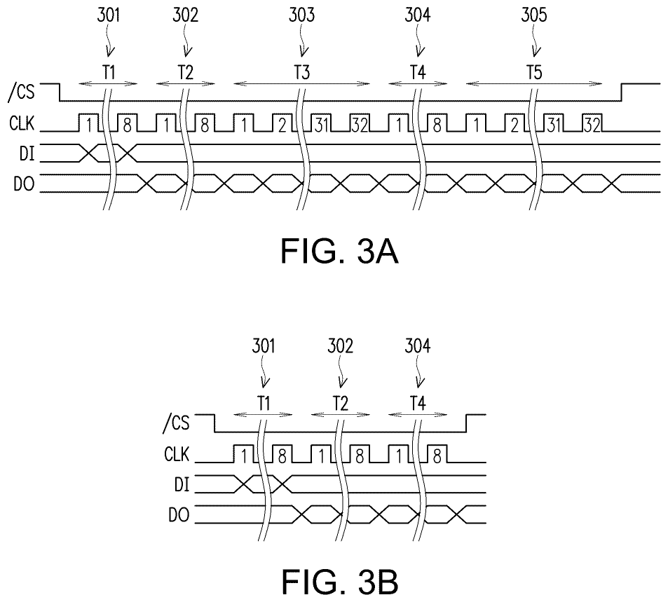

FIG. 3A and FIG. 3B illustrate waveform diagrams of signals in the memory device 100 when the time counter 125 is enabled or disabled in accordance with some embodiments. The signals illustrated in FIG. 3A and FIG. 3B includes signals at a chip selection terminal/CS, a clock terminal CLK, an input terminal DI and an output terminal DO. The signal at the chip selection terminal/CS is configured to select a chip among chips of the memory device 100. The low logic state of the signal at the chip selection terminal/CS in FIG. 3A and FIG. 3B represents a selected chip where the operation is going to be performed. The signal at the clock terminal CLK can be a system clock for operating the memory device 100. The signal at the input terminal DI represents commands to the memory device 100. When the sector erase needs to execute, the sector erase command can be issued via the input terminal DI. Furthermore, when the values of the status register 124 and/or the time value of the time counter 125 needs to be read out, the status register read command may be issued via the input terminal DI. The output terminal DO is configured to output data such as values of the status register 124 and/or the time value of the time counter 125.

Referring to FIG. 3A, when the configuration bit 126 is in the first logic state, the time value of the time counter 125 and the values of the status register 124 will be provided upon the status register read command. As shown in FIG. 3A, in a command input phase 301, the status register read command is issued to the input terminal DI. The status register read command may be provided to the input terminal DI in a time interval T1 corresponding to 8 clock cycles. In a status register output phase 302, the values of the status register 124 are output to the output terminal DO. The values of the status register 124 may be output during the time interval T2 corresponding to 8 clock cycles. In a time counter output phase 303, the time value of the time counter 125 is output to the output terminal DO. The time value of the time counter 125 may be output during the time interval T3 corresponding to 32 clock cycles. By analogy, the values of the status register 124 and the time value of the time counter 125 are output to the output terminal DO during a time interval T4 of the status register output phase 304 and during the time interval T5 of the time counter output phase 305, respectively. In this way, the values of the status register 124 and the time value of the time counter 125 can be output upon the status register read command.

Referring to FIG. 3B, when the configuration bit 126 is in the second logic state, the time counter 125 may be disabled and only the values of the status register 124 will be provided upon the status register read command. In other words, the time value of the time counter 125 will not be provided upon the status register read command. The same elements in FIG. 3A and FIG. 3B are illustrated by same reference numbers. A difference between the FIG. 3A and FIG. 3B is that in FIG. 3A, the time counter output phases 303 and 305 do not exist. Upon the issuance of the status register read command in the command input phase 301, only the values of the status register 124 are output during the status register output phases 302 and 304.

As shown in FIG. 3A and FIG. 3B, the time value of the time counter 125 may be selectively provided upon the status register read command by configuring the configuration bit 126. When the configuration bit 126 is in the first logic state, both the values of the status register 124 and the time value of the time counter 124 may be output to the output terminal DO. When the configuration bit 126 is in the second logic state, the time value of the time counter 125 is not output to the output terminal DO and only the values of the status register 124 are output to the output terminal DO.

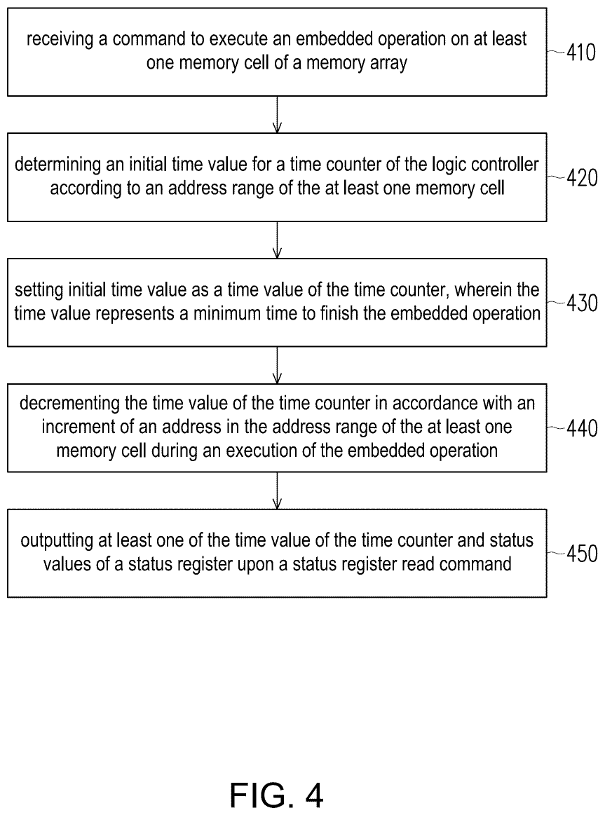

FIG. 4 illustrates a flowchart diagram of a method adapted to a memory device with a time counter in accordance with some embodiment. In step 410, a command to execute an embedded operation on at least one memory cell of the memory array is received. In step 420, the method determines an initial time value for a time counter of the logic controller according to an address range of the at least one memory cell. In step 430, the initial time value is set as a time value of the time counter, wherein the time value represents a minimum time to finish the embedded operation. In step 440, the time value of the time counter is decremented in accordance with an increment of an address in the address range of the at least one memory cell during an execution of the embedded operation. In step 450, at least one of the time value of the time counter and status values of a status register is output upon a status register read command.

In summary, a built-in time counter which holds a minimum time to finish an embedded operation to be executed on at least one memory cell is introduced. The time counter may be set in accordance with an address range of memory cells on which the embedded operation executes and a type of the embedded operation. The time counter is decremented in response to an address increment in the address range of memory cells. In this way, the power consumption of the memory device is reduced, as the minimum time to finish the embedded operation is known and it is not necessary to frequently read the status register for monitoring the status of the memory device. In addition, the information about the minimum time to finish the embedded operation may be used to optimize the performance of the memory device. The time counter can be configured by a configuration bit and the time value of the time counter can be output upon to a status register read command. When the configuration bit is a first logic state, both the time value of the time counter and values of the status register are output upon the status register read command. When the configuration bit is a second logic state, the time value of the time counter will not be output and only values of the status register are output upon the status register read command. In this way, the user does not need to feed the embedded operation specification information into their software since the estimated time to finish the embedded operation can be provided by the status register read. Furthermore, the time value of the time counter can be readable during different statuses including a suspend status of the memory device, thereby improving flexibility and operability of the memory device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a memory array, comprising a plurality of memory cells;
a logic controller, connected to the memory array, configured to execute an embedded operation on at least one memory cell among the memory cells of the memory array, wherein the logic controller comprises:
a time counter, configured to hold a time value representing a minimum time to finish the embedded operation, wherein the time value of the time counter is set according to an address range of the at least one memory cell, and the time value of the time counter is decremented in accordance with an increment of an address in the address range of the at least one memory cell during an execution of the embedded operation; and
an input/output (IO) circuit, configured to output the time value of the time counter.

2. The memory device of claim 1, wherein the logic controller further comprises:
a status register, recording at least one status values of the memory device, wherein
the time value of the time counter is read upon a status register read command, and the time value of the time counter is also readable during a suspend status of the memory device.

3. The memory device of claim 2, wherein the logic controller further comprises:
a configuration bit, configured to set whether to output the time value of the time counter upon the status register read command, wherein
when the configuration bit is a first logic state, the time value of the time counter and the status values of the status register are output upon the status register read command, and
when the configuration bit is a second logic state, the time value of the time counter is not output upon the status register read command and the status values of the status register are output upon the status register read command.

4. The memory device of claim 1, wherein-
the embedded operation comprises a plurality of sub-operations, and
the time value of the time counter is set according to the address range of the at least one memory cell and a type of each of the sub-operations.

5. The memory device of claim 4, wherein the logic controller further comprises:
at least one option bit, configured to set a clock frequency of the time counter.

6. The memory device of claim 4, wherein
the embedded operation comprises at least one of a sector erase, a block erase and a chip erase,
the sector erase is configured to erase a sector of the memory array;
the block erase is configured to erase a block which comprises a plurality of sectors of the memory array, and
the chip erase is configured to erase a chip which comprises a plurality of blocks of the memory array.

7. The memory device of claim 6, wherein
the sub-operations of the embedded operation comprise at least one of a pre-program operation, an erase operation, an erase verify operation, a soft verify operation, a soft program operation and a refresh operation, and
each of the sub-operations of the embedded operation is associated with a number of clock cycles.

8. The memory device of claim 7, wherein
during an execution of the pre-program operation, the erase verify operation, the soft verify operation, the soft program operation or the refresh operation, the time value of the time counter decrements by an amount corresponding to the number of clock cycles associated with the pre-program operation, the erase verify operation, the soft verify operation, the soft program operation or the refresh operation, respectively.

9. The memory device of claim 7, wherein
during an execution of the erase operation, the time value of the time counter is not decremented.

10. The memory device of claim 1, wherein the logic controller further comprises:
an address register, recording the address range of the at least one memory cell where the embedded operation executes; and
an address counter, configured to increase the address in the address range during the execution of the embedded operation.

11. A logic controller, configured to execute an embedded operation on at least one memory cell of a memory array, the logic controller comprising:
an address register, recording an address range of the at least one memory cell where the embedded operation executes;
an address counter, configured to increase an address in the address range during an execution of the embedded operation; and
a time counter, configured to hold a time value representing a minimum time to finish the embedded operation, wherein the time value is set according to the address range of the at least one memory cell, and the time value is decremented in accordance with an increment of the address in the address range of the at least one memory cell during the execution of the embedded operation.

12. The logic controller of claim 11, further comprising:
a status register, recording at least one status values of the memory device,
wherein the time value of the time counter is read upon a status register read command, and the time value of the time counter is readable during a suspend status of the memory device.

13. The logic controller of claim 12, further comprising:
a configuration bit, configured to set whether to output the time value of the time counter upon the status register read command, wherein
when the configuration bit is a first logic state, the time value of the time counter and the status values of the status register are output upon the status register read command, and
when the configuration bit is a second logic state, the time value of the time counter is not output upon the status register read command and the status values of the status register are output upon the status register read command.

14. The logic controller of claim 11, wherein
the embedded operation comprises a plurality of sub-operations, the sub-operations of the embedded operation comprise at least one of a pre-program operation, an erase operation, an erase verify operation, a soft verify operation, a soft program operation and a refresh operation,
each of the sub-operations of the embedded operation is associated with a number of clock cycles,
during an execution of the pre-program operation, the erase verify operation, the soft verify operation, the soft program operation or the refresh operation, the time value of the time counter decrements by an amount corresponding to the number of clock cycles associated with the pre-program operation, the erase verify operation, the soft verify operation, the soft program operation or the refresh operation, respectively, and
during an execution of the erase operation, the time value of the time counter is not decremented.

15. A method of a memory device comprising a memory array and a logic controller, the method comprising:
receiving a command to execute an embedded operation on at least one memory cell of the memory array;
determining an initial time value for a time counter of the logic controller according to an address range of the at least one memory cell;
setting initial time value as a time value of the time counter, wherein the time value represents a minimum time to finish the embedded operation;
decrementing the time value of the time counter in accordance with an increment of an address in the address range of the at least one memory cell during an execution of the embedded operation; and
outputting at least one of the time value of the time counter and status values of a status register upon a status register read command.

16. The method of claim 15, wherein outputting the at least one of the time value of the time counter and the values of the status register comprises:
outputting the status values of the status register and the time value of the time counter upon the status register read command when the configuration bit is a first logic state; and
outputting the status values of the status register upon the status register read command when the configuration bit is the second logic state.

17. The method of claim 15, wherein
the embedded operation comprises at least one of a sector erase, a block erase and a chip erase,
the sector erase is configured to erase a sector of the memory array;
the block erase is configured to erase a block which comprises a plurality of sectors of the memory array, and
the chip erase is configured to erase a chip which comprises a plurality of blocks of the memory array.

18. The method of claim 17, wherein
the embedded operation comprises a plurality of sub-operations which comprise at least one of a pre-program operation, an erase operation, an erase verify operation, a soft verify operation, a soft program operation and a refresh operation,
each of the sub-operations of the embedded operation is associated with a number of clock cycles.

19. The method of claim 18, wherein decrementing the time value of the time counter comprises:
decrementing the time value of the time counter by an amount corresponding to the number of clock cycles associated with the pre-program operation, the erase verify operation, the soft verify operation, the soft program operation or the refresh operation, during an execution of the pre-program operation, the erase verify operation, the soft verify operation, the soft program operation or the refresh operation.

20. The method of claim 19, wherein
during an execution of the erase operation, the time value of the time counter is not decremented.
